(19) United States
(12) Patent Application Publication
(10) Pub. No.: US 2016/0330883 A1
(43) Pub. Date: Nov. 10, 2016

(54) ASSEMBLING APPARATUS FOR BACKLIGHT

(71) Applicant: HON HAI PRECISION INDUSTRY CO., LTD., New Taipei (TW)

(72) Inventors: CHIEN-YU TSENG, New Taipei (TW); HUI-TING SHEN, New Taipei (TW); CHEN-JUNG FANG, New Taipei (TW); CHIH-HUANG LIEN, New Taipei (TW)

(21) Appl. No.: 14/809,457

(22) Filed: Jul. 27, 2015

(30) Foreign Application Priority Data
May 8, 2015 (TW) 104114828

(51) Int. Cl. H05K 13/04

(52) U.S. Cl. CPC H05K 13/0478

(57) ABSTRACT

An assembling apparatus includes a rotating table, a plurality of assembling mechanisms, at least one assembling fixture, and a turnover mechanism configured to flip the assembling fixture. The rotating table includes a plurality of working stations. Each of the plurality of working stations corresponds to each of the plurality of assembling mechanisms. The at least one assembling fixture is positioned on the plurality of working stations. The plurality of assembling mechanisms are configured to supply and locate kinds of assemblies of a backlight module, and the kinds of the components of the backlight module are assembled into the at least one assembling fixture in turn.

### FIELD

The subject matter herein generally relates to industrial assembling processes.

### BACKGROUND

When assembling backlight modules, an artificial mean of assembling is usually applied. A plurality of reflective films must be orderly attached to a back cover. Then a frame is received in a fixture, and a light guide plate is pressed to the frame. Finally, a plurality of optical films are attached to the light guide plate.

### BRIEF DESCRIPTION OF THE DRAWINGS

Implementations of the present technology will now be described, by way of example only, with reference to the attached figures.

FIG. 1 is an exploded, isometric view of an embodiment of a backlight module.

FIG. 2 is top view of an embodiment of an assembling apparatus in relation to the backlight module of FIG. 1.

FIG. 3 is a flow chart of an assembling method for using the assembling apparatus of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”, it specifically indicates open-ended inclusion or membership in the so-described combination, group, series and the like.

The present disclosure is described in relation to an assembling apparatus.

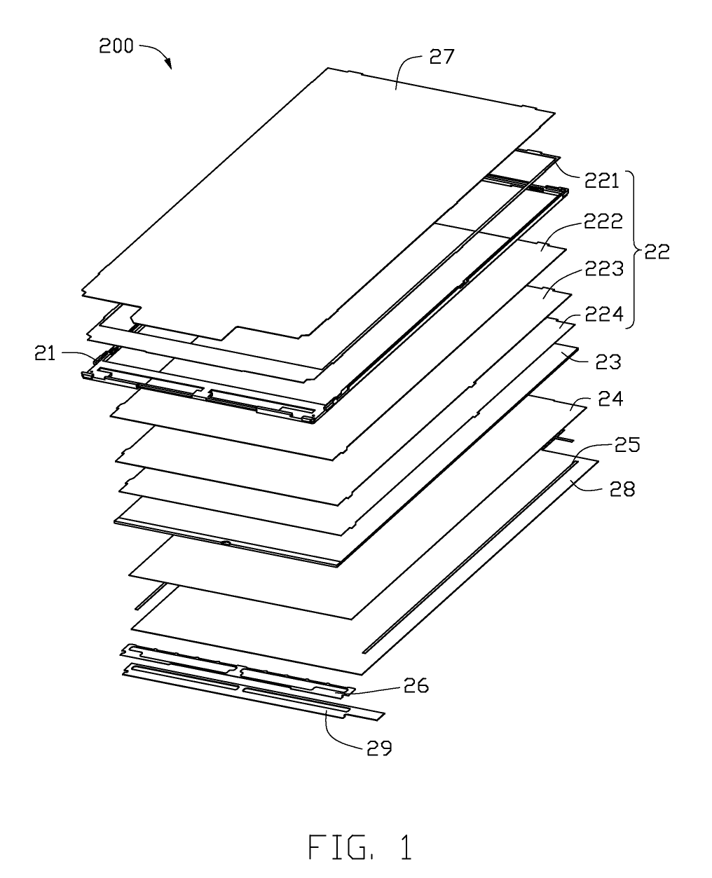

FIG. 1 illustrates an embodiment of a backlight module 200. The backlight module 200 can include a frame 21, a plurality of optical films 22, a light guide plate 23, a reflective film 24, a back cover double-sided tape 25, and a double-sided tape for a flexible printed circuit board (double-sided FPC tape) 26. The light guide 23 can be received in the frame 21. The optical films 22 and the reflective film 24 can be respectively attached to two opposite surfaces (not shown in FIG. 1) of the light guide plate 23. The optical films 22 can include a shading film 221, an upper brightness enhancement film 222, a lower brightness enhancement film 223, and a diffusion film 224 stacked together in order.

The backlight module 200 can further include an upper protective film 27, a back cover protective film 28, an FPC protective film 29, and a light source (not shown in FIG. 1).

The upper protective film 27 can be attached to the optical films 22. The back cover protective film 28 can be attached to a surface (not labeled) of the reflective film 24 far away from the light guide plate 23 by the back cover double-sided tape 25. The FPC protective film 29 can be attached to the light guide plate 23 by the double-sided FPC tape 26. The light source (not shown in FIG. 1) can be positioned on the light guide plate 23 by the double-sided FPC tape 26.

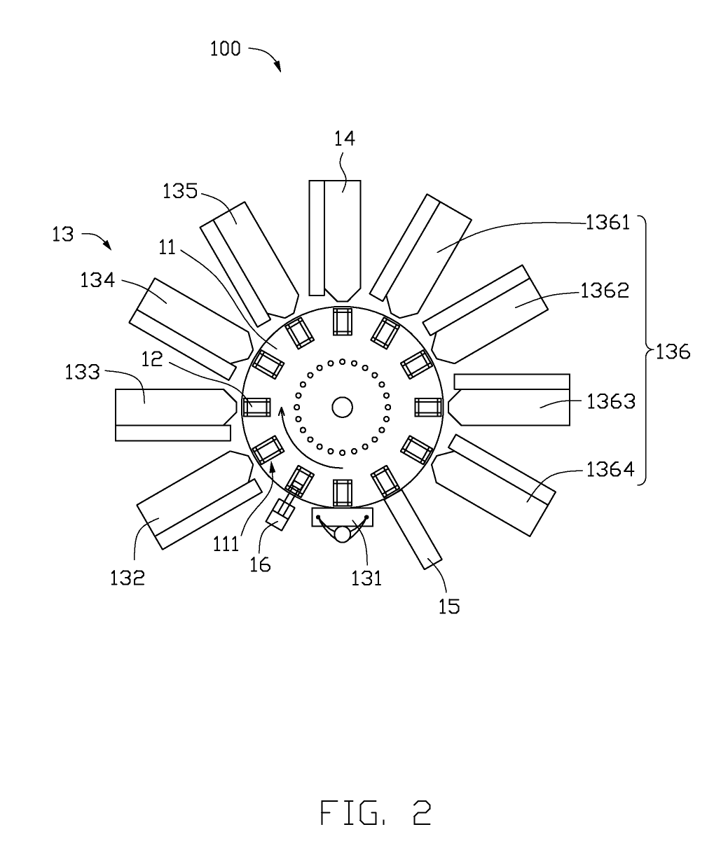

FIG. 2 illustrates an embodiment of an assembling apparatus 100. The assembling apparatus 100 can include a rotating table 11, at least one assembling fixture 12, a plurality of assembling mechanisms 13, a turnover mechanism 14, and an unloading mechanism 15. The assembling fixture 12 can be positioned on the rotating table 11. The plurality of assembling mechanisms 13, the turnover mechanism 14 and the unloading mechanism 15 can be positioned around the rotating table 11. The plurality of assembling mechanisms 13 can be configured to supply kinds of assembling in relation to the backlight module 200, such as the frame 21, the optical films 22, the light guide plate 23, the reflective film 24, the back cover double-sided tape 25, the double-sided FPC tape 26, and so on. The plurality of assembling mechanisms 13 can include a frame assembling mechanism 131, a light guide plate assembling mechanism 132, a double-sided FPC tape assembling mechanism 133, a reflective film assembling mechanism 134, a back cover double-sided tape assembling mechanism 135, and an optical film assembling mechanism 136. The turnover mechanism 14 can be configured to flip the assembling fixture 12. The unloading mechanism 15 can be configured to place the assembled backlight module 200 on a transferring tape (not shown in FIG. 2).

In the illustrated embodiment, the assembling apparatus 100 can further include a dust removing mechanism 16. The dust removing mechanism 16 can be positioned between the frame assembling mechanism 131 and the light guide plate assembling mechanism 132. The dust removing mechanism 16 can be configured to clean the frame 21. The dust removing mechanism 16 can be a mechanism to remove dust ionically.

The rotating table 11 can be substantially circular and can rotate around a center (not labeled) of the rotating table 11. The rotating table 11 can include a plurality of working stations 111. Each of the working stations 111 can correspond to one of the assembling mechanisms 13 or to the turnover mechanism 14 or to the dust removing mechanism 16 or to the unloading mechanism 15. In the illustrated embodiment, a quantity of the assembling fixtures 12 can be equal to a quantity of the working stations 111. Each of the assembling fixtures 12 can be correspondingly positioned on each of the working stations 111.

In the illustrated embodiment, each of the assembling mechanisms 13 can include a feeding module (not shown in FIG. 2), a manipulator (not shown in FIG. 2), and an automatic location platform (not shown in FIG. 2). The feeding module (not shown in FIG. 2) can be configured to supply the components of the backlight module 200, such as the light guide plate 23, the reflective film 24, and so on. The manipulator (not shown in FIG. 2) can be configured to hold and assemble the components of the backlight module 200 to the assembling fixture 12.

The automatic location platform (not shown in FIG. 2) can be configured to locate and hold the components of the backlight module 200. Therefore, the manipulator (not shown in FIG. 2) can present the components of the backlight module 200 on the automatic location platform (not shown in FIG. 2), and can assemble the components of the backlight module 200 to the assembling fixture 12 to avoid positioning errors in relation to the components of the backlight module 200.

In the illustrated embodiment, the optical film assembling mechanism 136 can include a diffusion film assembling module 1361, a lower brightness enhancement film assembling module 1362, an upper brightness enhancement film assembling module 1363, and a shading film assembling module 1364. The diffusion film assembling module 1361, the lower brightness enhancement film assembling module 1362, the upper brightness enhancement film assembling module 1363, and the shading film assembling module 1364 can be positioned around the rotating table 11 in turn.

In the illustrated embodiment, the turnover mechanism 14 can be positioned between the back cover double-sided tape assembling mechanism 135 and the diffusion film assembling module 1361. The turnover mechanism 14 can be configured to flip the assembling fixtures 12 by 180 degrees. The unloading mechanism 15 can be positioned between the frame assembling mechanism 131 and the shading film assembling module 1364.

In the illustrated embodiment, the double-sided FPC tape assembling mechanism 133, the back cover double-sided tape assembling mechanism 135, and the optical film assembling mechanism 136 can include a rolling film module (not shown in FIG. 2). The rolling film module can be configured to remove a protective film of the back cover double-sided tape 25, of the double-sided FPC tape 26, and of the optical films 22.

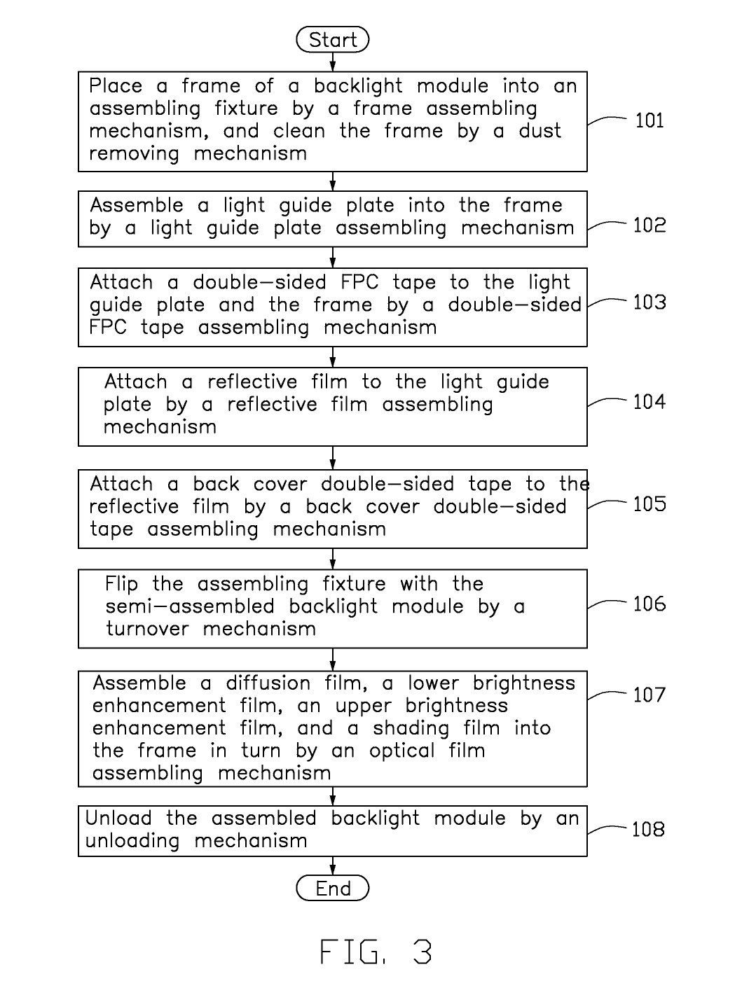

Referring to FIG. 3, a flowchart is presented in accordance with an example embodiment. An assembling method of the assembling apparatus 100 is provided by way of example, as there are a variety of ways to carry out the method. The assembling method of the assembling apparatus 100 described below can be carried out using the configurations illustrated in FIGS. 1 to 2, for example, and various elements of these figures are referenced in explaining an example assembling method of the assembling apparatus 100. Each block shown in FIG. 3 represents one or more processes, methods, or subroutines, carried out in the example assembling method of the assembling apparatus 100. Additionally, the illustrated order of blocks is by example only and the order of the blocks can change. The assembling method of the assembling apparatus 100 can begin at block 101.

At block 101, the frame 21 can be placed on the automatic location platform of the frame assembling mechanism 131 by the manipulator of the frame assembling mechanism 131. The frame 21 can be located and can be placed on the assembling fixture 12 from the automatic location platform of the frame assembling mechanism 131 by the manipulator of the frame assembling mechanism 131. The frame 21 in the assembling fixture 12 can be moved to the dust removing mechanism 16 by the rotating table 11 and can be cleaned by the dust removing mechanism 16.

At block 102, the frame 21 in the assembling fixture 12 can be moved to the light guide plate assembling mechanism 132 by the rotating table 11, and one of the light guide plates 23 in the light guide plate assembling mechanism 132 can be presented by the automatic location platform of the light guide plate assembling mechanism 132. The light guide plates 23 in the automatic location platform of the light guide plate assembling mechanism 132 can be assembled to the frame 21 in the assembling fixture 12 by the manipulator of the light guide plate assembling mechanism 132.

At block 103, the light guide plates 23 and the frame 21 in the assembling fixture 12 can be moved to the double-sided FPC tape assembling mechanism 133 by the rotating table 11. The protective film of the double-sided FPC tape 26 can be removed by the rolling film module of the double-sided FPC tape assembling mechanism 133. The double-sided FPC tape 26 can be presented by the automatic location platform of the double-sided FPC tape assembling mechanism 133. The double-sided FPC tape 26 can be attached to the light guide plate 23 and the frame 21 by the manipulator of the double-sided FPC tape assembling mechanism 133.

At block 104, the light guide plates 23 and the frame 21 in the assembling fixture 12 can be moved to the reflective film assembling mechanism 134 by the rotating table 11. The protective film of the reflective film 24 can be removed by the rolling film module of the reflective film assembling mechanism 134. The reflective film 24 can be presented by the automatic location platform of the reflective film assembling mechanism 134. The reflective film 24 can be attached to the light guide plate 23 by the manipulator of the reflective film assembling mechanism 134.

At block 105, the light guide plates 23, the frame 21, and the reflective film 24 in the assembling fixture 12 can be moved to the back cover double-sided tape assembling mechanism 135 by the rotating table 11. The protective film of the back cover double-sided tape 25 can be removed by the rolling film module of the back cover double-sided tape assembling mechanism 135. The back cover double-sided tape 25 can be presented by the automatic location platform of the back cover double-sided tape assembling mechanism 135. The back cover double-sided tape 25 can be attached to the reflective film 24 by the manipulator of the back cover double-sided tape assembling mechanism 135.

At block 106, the semi-assembled backlight module 200 in the assembling fixture 12 can be moved to the turnover mechanism 14 by the rotating table 11, and the semi-assembled backlight module 200 and the assembling fixture 12 can be flipped by 180 degrees by the turnover mechanism 14.

At block 107, the semi-assembled backlight module 200 and the assembling fixture 12 can be moved to the optical film assembling mechanism 136 by the rotating table 11. The diffusion film 224 can be assembled into the frame 21 by the diffusion film assembling module 1361. The protective film of the lower brightness enhancement film 223 can be removed, and the lower brightness enhancement film 223 can be assembled into the frame 21 and can be positioned upon the diffusion film 224 by the lower brightness enhancement film assembling module 1362. The protective film of the upper brightness enhancement film 222 can be removed, and the upper brightness enhancement film 222 can be assembled into the frame 21 and can be positioned upon the lower brightness enhancement film 223 by the upper brightness enhancement film assembling module 1363. The shading film 221 can be assembled into the frame 21 and can be positioned upon the upper brightness enhancement film 222 by the shading film assembling module 1364.

At block 108, the assembled backlight module 200 and the assembling fixture 12 can be moved to the unloading mechanism 15 by the rotating table 11, and the assembled backlight module 200 can be unloaded by the unloading mechanism 15.

In at least one embodiment, the double-sided FPC tape assembling mechanism 133 and the back cover double-sided tape assembling mechanism 135 can also supply and assemble the FPC protective film 29 and the back cover protective film 28 respectively.

In at least one embodiment, the diffusion film assembling module 1361, the lower brightness enhancement film assembling module 1362, the upper brightness enhancement film assembling module 1363, and the shading film assembling module 1364 of the optical film assembling mechanism 136 can be replaced by other assembling mechanisms (not shown in FIG. 2) according to the nature of the optical films 22.

As described above, the backlight module 200 can be moved to each of the assembling mechanisms 13 by the rotating table 11 and can undergo automatic assembly by each of the assembling mechanisms 13, to improve the assembling efficiency. The backlight module 200 can be flipped by the turnover mechanism to enable the components in relation to two opposite surfaces of the frame 21 of the backlight module 200 to be automatically assembled.

The embodiments shown and described above are only examples. Many details are often found in the art such as the other features of an assembling apparatus. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including matters of shape, size and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. An assembling apparatus configured to assemble a backlight module, the assembling apparatus comprising:
a rotating table comprising a plurality of working stations;
a plurality of assembling mechanisms positioned around the rotating table and are configured to supply and locate kinds of components of the backlight module;
at least one assembling fixture positioned on the rotating table and on the plurality of working stations; and
a turnover mechanism positioned between two adjacent assembling mechanisms and configured to flip the at least one assembling fixture;
wherein each of the plurality of working stations corresponds to each of the plurality of assembling mechanisms, and the components of the backlight module are assembled into the at least one assembling fixture in turn.

2. The assembling apparatus as claimed in claim 1, wherein the plurality of assembling mechanisms comprising:
a frame assembling mechanism;
a light guide plate assembling mechanism;
a reflective film assembling mechanism; and
an optical film assembling mechanism;
wherein the frame assembling mechanism, the light guide plate assembling mechanism, the reflective film assembling mechanism, and the optical film assembling mechanism are positioned around the rotating table in turn.

3. The assembling apparatus as claimed in claim 2, wherein the plurality of assembling mechanisms further comprising:
a double-sided flexible printed circuit board (FPC) tape assembling mechanism; and
a back cover double-sided tape assembling mechanism;
wherein the double-sided FPC tape assembling mechanism is positioned between the light guide plate assembling mechanism and the reflective film assembling mechanism, and the back cover double-sided tape assembling mechanism is positioned between the reflective film assembling mechanism and the optical film assembling mechanism.

4. The assembling apparatus as claimed in claim 3, wherein the double-sided FPC tape assembling mechanism, the back cover double-sided tape assembling mechanism, and the optical film assembling mechanism are configured to remove a protective film of the components of the backlight module.

5. The assembling apparatus as claimed in claim 3, wherein the turnover mechanism is positioned between the back cover double-sided tape assembling mechanism and the optical film assembling mechanism and configured to flip the at least one assembling fixture by 180 degrees.

6. The assembling apparatus as claimed in claim 2, wherein the optical film assembling mechanism comprising:
a diffusion film assembling module;
a lower brightness enhancement film assembling module;
an upper brightness enhancement film assembling module; and
a shading film assembling module.

7. The assembling apparatus as claimed in claim 2, wherein the assembling apparatus further comprises an unloading mechanism adjacent to the frame assembling mechanism and configured to unload the backlight module.

8. The assembling apparatus as claimed in claim 2, wherein the assembling apparatus further comprises a dust removing mechanism positioned between the frame assembling mechanism and the light guide plate assembling mechanism.

9. The assembling apparatus as claimed in claim 1, wherein a quantity of the assembling fixtures is equal to a quantity of plurality of working stations, and each of the assembling fixtures is correspondingly positioned on each of the working stations.
